(19) United States
(12) Patent Application Publication
(10) Pub. No.: US 2013/0228811 A1
(43) Pub. Date: Sep. 5, 2013

(54) LIGHT SOURCE DEVICE HAVING LIGHT EMITTING DIODE

(71) Applicants: CHUNG-MIN CHANG, Hukou (TW); HSUEN-FENG HU, Hukou (TW); YU-WEI TSAI, Hukou (TW); CHIEN-LIN CHANG-CHIEN, Hukou (TW)

(72) Inventors: CHUNG-MIN CHANG, Hukou (TW); HSUEN-FENG HU, Hukou (TW); YU-WEI TSAI, Hukou (TW); CHIEN-LIN CHANG-CHIEN, Hukou (TW)

(73) Assignee: ADVANCED OPTOELECTRONIC TECHNOLOGY, INC., Hsinchu Hsien (TW)

(21) Appl. No.: 13/602,314

(22) Filed: Sep. 3, 2012

(30) Foreign Application Priority Data
Mar. 1, 2012 (CN) 201210051440.0

(51) Int. Cl. H01L 33/58; H01L 33/50

(52) U.S. Cl. 257/98; 257/E33.061; 257/E33.074

(57) ABSTRACT

An LED light source device includes an LED light source, a first powder layer located at a light path of the LED light source and a lamp shell located around the LED light source and the first powder layer. The lamp shell defines a receiving room. A second powder layer is formed on an inner surface of the lamp shell. The first powder layer and the second powder layer each have a characteristic of scattering light.

### BACKGROUND

1. Technical Field

The present disclosure relates to illumination, and more particularly to an LED (light emitting diode) light source device having a uniform distribution of light output.

2. Description of Related Art

LEDs have been widely promoted as light sources of electronic devices owing to many advantages, such as high luminosity, low operational voltage and low power consumption. However, as a point light source, a light-emitting angle of the LED is only 120°, and a light field of the LED is not uniform.

Therefore, an LED light source device which is capable of overcoming the above described shortcomings is desired.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 shows a schematic, cross sectional view of an LED light source device in accordance with a first embodiment of the present disclosure.

FIG. 2 shows a schematic, cross sectional view of an LED light source device in accordance with a second embodiment of the present disclosure.

FIG. 3 shows a schematic, cross sectional view of an LED light source device in accordance with a third embodiment of the present disclosure.

### DETAILED DESCRIPTION

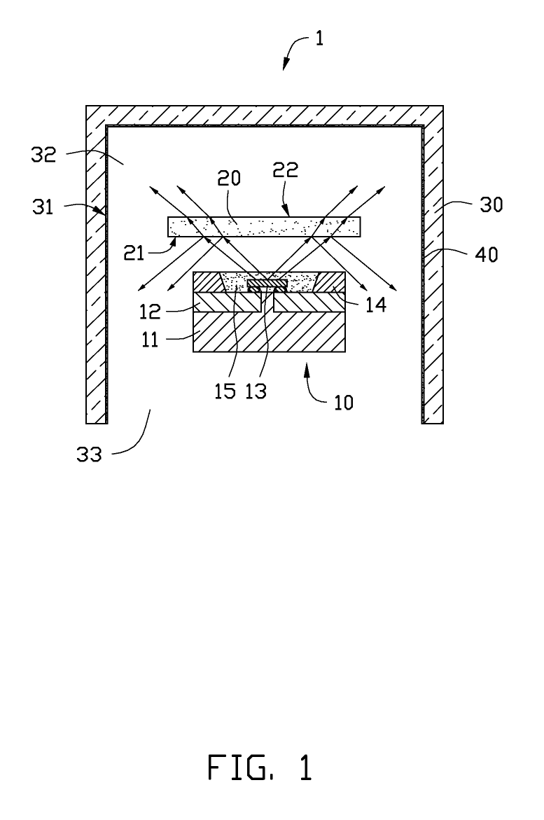

Referring to FIG. 1, an LED light source device 1 in accordance with a first embodiment of the present disclosure includes an LED light source 10, a first powder layer 20, a lamp shell 30 covering the LED light source 10 and the first powder layer 20, and a second powder layer 40 coated on an inner surface 31 of the lamp shell 30.

In this embodiment, the LED light source 10 is an LED package, and includes a substrate 11 with an electrode structure 12, an LED chip 13 electrically connected with the electrode structure 12, a reflection layer 14 surrounding the LED chip 13, and an encapsulation layer 15 sealing the LED chip 13.

The first powder layer 20 is located on a light path of the LED light source 10 and spaced from the LED light source 10. In this embodiment, the first powder layer 20 has a plate shape, and includes a lower surface 21 facing the LED light source 10, and an upper surface 22 opposite to the lower surface 21. The first powder layer 20 has a characteristic of scattering light. Light emitted from the LED light source 10 is scattered by the first powder layer 20 into multi-directional light, so the light-emitting angle of the LED light source 10 is increased, and a light intensity distribution of the light field of the LED light source 10 is uniform. The first powder layer 20 can be made of SiO₂ powder, Al₂O₃ powder, silicate powder or a mixture thereof. Alternatively, the first powder layer 20 can be directly attached on the encapsulation layer 15 of the LED light source 10. In addition, the first powder layer 20 can be shaped into a block of other shape.

The lamp shell 30 is located outside of the LED light source 10 and the first powder layer 20, and includes an inner surface 31. The inner surface 31 defines a receiving room 32. In this embodiment, the lamp shell 30 is transparent or translucent. The LED light source 10 and the first powder layer 20 are received in the receiving room 32. The lamp shell 30 has a shape of a hollow cube, with an opening 33 defined in a bottom side thereof.

The second powder layer 40 is coated on the inner surface 31 of the lamp shell 30, and has a characteristic of scattering light. The second powder layer 40 can be made of SiO₂powder, Al₂O₃ powder, silicate powder or a mixture thereof.

During operation of the LED light source 10, the light emitted from the LED light source 10 travels toward the lower surface 21 of the first powder layer 20. A part of the light is reflected by the lower surface 21 to travel slantwise downwardly toward the second powder layer 40, from where the light is reflected by the second powder layer 40 out of the lamp shell 30 via the opening 33 or refracted by the second powder layer 40 to radiate out of the lamp shell 30 via the lamp shell 30. Due to the light scattering characteristic of the first powder layer 20, another part of the light travelling toward the lower surface 21 is refracted to the upper surface 22 of the first powder layer 20 when it is incident onto the first powder layer 20. The another part of the light successively passes through the upper surface 22 of the first powder layer 20, and is finally projected upwardly towards the second powder layer 40 via the receiving room 32. At the second powder layer 40, the light is scattered thereby to radiate out of the lamp shell 30 via the lamp shell 30 or the opening 33. After being scattered by the first powder layer 20 and the second powder layer 40, the light travels outward via the lamp shell 30 and the opening 33, along various directions. Therefore, the light-emitting angle of the LED light source device 1 is increased, and a light intensity distribution of the light field of the LED light source device 1 is uniform.

Additionally, the first powder layer 20 and the second powder layer 40 can be respectively made of a single color phosphor material, or made of multi-color phosphor materials. The phosphor materials of the first powder layer 20 and the second powder layer 40 can be the same or different, according to actual requirement. The first and second powder layers 20, 40 can be alternately stacked by phosphor materials and powder materials, such as SiO₂, Al₂O₃ or silicate.

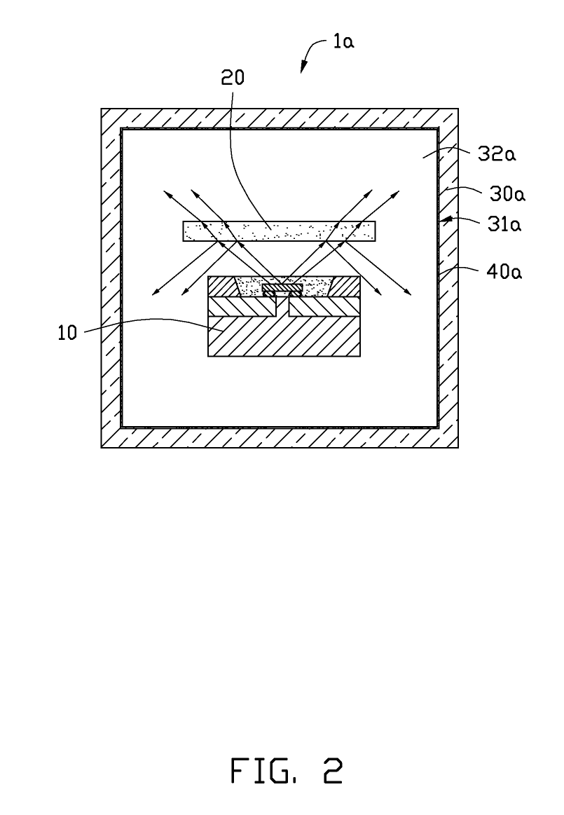

Referring to FIG. 2, an LED light source device 1 a in accordance with a second embodiment of the present disclosure is similar to the LED light source device 1 in the first embodiment. Different from the LED light source device 1 of the first embodiment, the LED light source device 1 a includes a closed lamp shell 30a. The lamp shell 30a has an inner surface 31a, and the inner surface 31a defines a closed receiving room 32a. The second powder layer 40a is coated on the inner surface 31a.

During operation of the LED light source 10, the light emitted from the LED light source 10 travels toward the lower surface 21 of the first powder layer 20. A part of the light is reflected by the lower surface 21 to travel slantwise downwardly toward the second powder layer 40a, from where the light is reflected by the second powder layer 40a to another part of the second powder layer 40 or refracted by the second powder layer 40a to radiate out of the lamp shell 30a via the lamp shell 30a. Due to the light scattering characteristic of the first powder layer 20, another part of the light travelling toward the lower surface 21 is refracted to the upper surface 22 of the first powder layer 20 when it is incident onto the first powder layer 20. The another part of the light successively passes through the upper surface 22 of the first powder layer 20, and is finally projected upwardly towards the second powder layer 40a via the receiving room 32a. At the second powder layer 40a, the light is scattered thereby to radiate out of the lamp shell 30a via the lamp shell 30a. After being scattered by the first powder layer 20 and the second powder layer 40a, the light travels outward via the lamp shell 30a along various directions. Therefore, the light-emitting angle of the LED light source device 1a is increased, and a light intensity distribution of the light field of the LED light source device 1a is uniform.

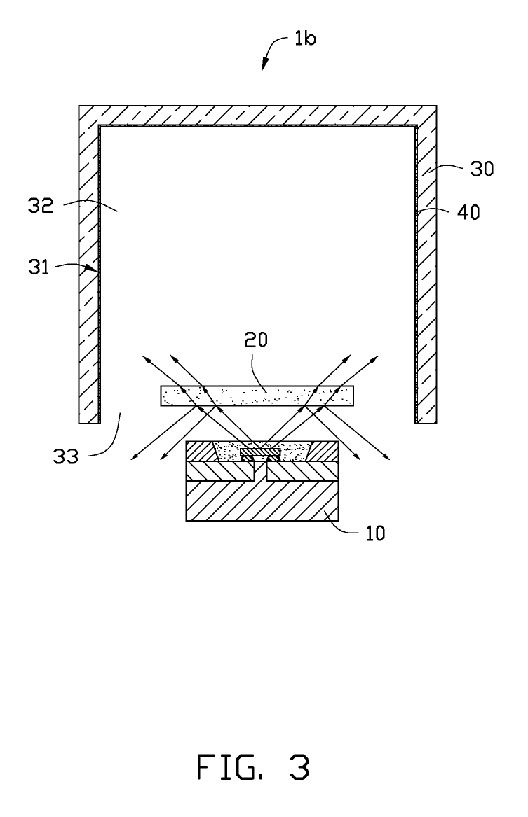

Referring to FIG. 3, an LED light source device 1b in accordance with a third embodiment of the present disclosure is similar to the LED light source device 1 in the first embodiment. Different from the LED light source device 1 of the first embodiment, the LED light source 10 is located outside of the receiving room 32 of the lamp shell 30, and adjacent to the opening 33.

During operation of the LED light source 10, the light emitted from the LED light source 10 travels toward the lower surface 21 of the first powder layer 20. A part of the light emitted from the LED light source 10 is reflected by the lower surface 21 to an exterior of the LED light source device 1b. Due to the light scattering characteristic of the first powder layer 20, another part of the light travelling toward the lower surface 21 is refracted to the upper surface 22 of the first powder layer 20 when it is incident onto the first powder layer 20. The another part of the light successively passes through the upper surface 22 of the first powder layer 20, and is finally projected upwardly towards the second powder layer 40 via the receiving room 32. At the second powder layer 40a, the light is scattered thereby to radiate out of the lamp shell 30 via the lamp shell 30 or the opening 33. After being scattered by the first powder layer 20 and the second powder layer 40, the light travels outward via the lamp shell 30 and the opening 33 along various directions. Therefore, the light-emitting angle of the LED light source device lb is increased, and a light intensity distribution of the light field of the LED light source device 1b is uniform.

FIGS. 1-3 only succinctly illustrate the scattering paths of the light emitted from the LED light source 10, without introducing other structures of the LED light source device 1, 1a, 1b. Thus, the LED light source device 1, 1a, 1b can also include other unmentioned structures, such as a lamp holder. Further, the lamp shell 30, 30a is not limited to be a hollow cube, and for example, the lamp shell 30, 30a can also be a hollow globe or a hollow ellipsoid.

Particular embodiments are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. An LED light source device, comprising:
an LED light source; and
a first powder layer located at a light path of the LED light source, the first powder layer having a characteristic of scattering light.

2. The LED light source device of claim 1, wherein the first powder layer is spaced from the LED light source.

3. The LED light source device of claim 1, wherein the first powder layer is made of SiO₂ powder, Al₂O₃ powder, silicate powder or a mixture thereof.

4. The LED light source device of claim 1, wherein the first powder layer is made of phosphor materials.

5. The LED light source device of claim 1, wherein the first powder layer has alternately stacked layers made of SiO₂ powder, Al₂O₃ powder, silicate powder or phosphor materials.

6. The LED light source device of claim 1, further comprising a lamp shell covering the LED light source and the first powder layer, the lamp shell being transparent or translucent, and defining a receiving room, a second powder layer being formed on the lamp shell, the second powder layer having a characteristic of scattering light.

7. The LED light source device of claim 6, wherein the second powder layer is made of SiO₂ powder, Al₂O₃ powder, silicate powder or a mixture thereof.

8. The LED light source device of claim 6, wherein the second powder layer is made of phosphor materials.

9. The LED light source device of claim 6, wherein the second powder layer has alternately stacked layers made of SiO₂ powder, Al₂O₃ powder, silicate powder or phosphor materials.

10. The LED light source device of claim 6, wherein the LED light source and the first powder layer are received in the receiving room.

11. The LED light source device of claim 10, wherein the lamp shell defines an opening.

12. The LED light source device of claim 10, wherein the receiving room of the lamp shell is a closed space.

13. The LED light source device of claim 6, wherein one side of the lamp shell away from the first powder layer is not sealed and defines an opening, the LED light source being located outside of the receiving room and adjacent to the opening.

14. The LED light source device of claim 1, wherein the LED light source comprises an LED chip and an encapsulation layer sealing the LED chip.

15. An LED light source device, comprising:
an LED light source; and
a lamp shell covering the LED light source, the lamp shell being transparent or translucent, and defining a receiving room, a powder layer being formed on an inner surface of the lamp shell, the powder layer having a characteristic of scattering light.

16. The LED light source device of claim 15, wherein the lamp shell defines an opening in one side thereof.

17. The LED light source device of claim 16, wherein the LED light source is received in the receiving room.

18. The LED light source device of claim 16, wherein the LED light source is located outside of the receiving room and adjacent to the opening.

19. The LED light source device of claim 15, wherein the receiving room of the lamp shell is a closed space.

20. The LED light source device of claim 15, wherein the powder layer is made of SiO₂ powder, Al₂O₃ powder, silicate powder or a mixture thereof.

21. The LED light source device of claim 15, wherein the powder layer is made of phosphor materials.

22. The LED light source device of claim 15, wherein the powder layer has alternately stacked layers made of SiO₂ powder, Al₂O₃ powder, silicate powder or phosphor materials
